(19) United States
(12) Patent Application Publication
(10) Pub. No.: US 2018/0034297 A1
(43) Pub. Date: Feb. 1, 2018

(54) METHOD OF ASSISTING USE OF AN ELECTRONIC DEVICE ON-BOARD A VEHICLE

(71) Applicant: Jaguar Land Rover Limited, Coventry, Warwickshire (GB)

(72) Inventors: Matt JONES, Coventry, Warwickshire (GB); Paul WILES, Coventry, Warwickshire (GB)

(21) Appl. No.: 15/550,999

(22) PCT Filed: Feb. 23, 2016
(86) PCT No.: PCT/EP2016/053718

§ 371 Date: Aug. 14, 2017

(30) Foreign Application Priority Data
Feb. 25, 2015 (GB) 1503100.8

(51) Int. Cl. H02J 7/00; B60K 35/00

(52) U.S. Cl. CPC H02J 7/0047; B60K 35/00; H02J 2007/005

(57) ABSTRACT

Aspects of the disclosure relate to a method of assisting the use of a portable and rechargeable consumer electronic device (50) on-board a vehicle (20). Advantageously the method may be utilised in a motor vehicle and comprises determining that a portable consumer electronic device (50), such as a smartphone is connected to a controller (90) on-board the vehicle. The controller may form part of an infotainment system. The method then involves determining a charge characteristic of that consumer electronic device (50) and, in dependence upon that charge characteristic, the method includes issuing information (67) about the location of one or more charging ports (18a, 18b, 18c) that are provided on the vehicle (20). In this way the user of the device is both warned about a low battery level and guided to plug-in locations to assist the user of the portable consumer electronic device (50).

### TECHNICAL FIELD

The present disclosure relates to method of assisting use of an electronic device on-board a vehicle and particularly, but not exclusively, to a method that determines a charge characteristic of a consumer electronic device on-board the vehicle and, in dependence upon the determined charge characteristic, issues information about the location of one or more charging ports, for example illuminates charging ports to assist the user of the device in realising the charge characteristic and the location charging facilities. The invention finds advantageous application in motor vehicles, but may find advantageous application in other vehicles such as trains, planes and ferries and also in buildings such as homes and offices.

Aspects of the invention relate to a method, to a controller, to an infotainment system and to a vehicle.

### BACKGROUND

Many vehicles including motor vehicles, planes and trains accommodate passengers who bring on-board their own portable consumer electronic device such as a phone, smartphone, tablet computer, laptop computer and video gaming device. Such portable consumer electronic devices are often connectable with infotainment and other systems on-board the vehicles. For example, in a motor vehicle, a smartphone is connectable to a head unit of an infotainment system and this permits the infotainment system to broadcast through its speakers music stored on the smartphone and/or telephone conversations held using the smartphone. Such portable consumer electronic devices are typically rechargeable.

It has been recognised by the present applicant that low levels of electrical charge of smartphones and other portable consumer electronic devices can result in degraded performance of the device or even total shut down of the device, such that some or all functions of the device can no longer be performed. Problems associated with reduced function of the portable consumer electronic device due to low or zero battery charge may include, for example: loss of data; compromise or loss of a connection to a cloud based service, mobile telecommunications network and/or an infotainment or other system on-board a vehicle; loss of or poor broadcasting of music; poor telephone conversation broadcasting; and entire loss of ability to broadcast a telephone conversation or other infotainment transmission.

It is an aim of the present invention to provide an improvement in the field of infotainment and similar systems on-board vehicles that has particular application for motor vehicles. The invention may be utilised in applications for vehicles other than motor vehicles and may be utilised in applications other than for vehicles. For example, it is foreseen that the invention may have application in buildings, for example houses and offices.

### SUMMARY OF THE INVENTION

Aspects of the invention provide a method, a controller, an infotainment system and a vehicle as claimed in the appended claims.

According to an aspect of the invention, there is provided a method of assisting use of a portable and rechargeable consumer electronic device on-board a vehicle. The method comprises determining a charge characteristic of the consumer electronic device; and in dependence upon said determined charge characteristic, issuing information about the location of one or more charging ports on-board said vehicle. The information may assist a user of the portable consumer electronic device. In this way a consumer whose electronic device is low on charge is alerted to the locations of charging facilities so that they can plug their electronic device into a local electricity power supply and thereby prevent the device becoming unusable; and/or mitigate against loss of data; and/or mitigate against compromised connectivity and/or poor broadcasting/transmission of services such as telephone conversation and navigational information provided by the portable and rechargeable consumer electronic device.

Optionally, the method comprises determining that a consumer electronic device is in communication with a controller on the vehicle;

Optionally, determining that a consumer electronic device is in communication with (in other words is connected to) a controller on-board the vehicle comprises: receiving data from the consumer electronic device, which data comprises one or more of the following: charge level of a battery of the consumer electronic device; identity of the battery of the consumer electronic device; and/or type of consumer electronic device.

Optionally, the consumer electronic device is in communication with a controller of a vehicle system on-board the vehicle by means of a wireless connection.

In some embodiments, determining a charge characteristic may include: receiving data relating to one or more of the following: charge level of a battery of the consumer electronic device; and rate of discharge of a battery of the consumer electronic device. In this way a user whose device has an acceptable level of charge (remaining battery life) that is being used up quickly will still be alerted to the locations of charging facilities so that they can plug their electronic device into a local electronic power supply and thereby prevent the device becoming unusable.

Optionally, the step of issuing information comprises explicitly issuing charge characteristic information. Explicitly issuing charge characteristic information may comprise: issuing an audible or visual warning that incorporates a statement about: the charge characteristic of the consumer electronic device; the charge level of the battery of the consumer electronic device; and/or the rate of discharge of the battery of the consumer electronic device. As such the user may be explicitly informed by a textual message, an audible message or other obvious warning or alert that the charge characteristic of their device is considered to be inadequate.

Additionally or alternatively, the step of issuing information may comprise implicitly issuing charge characteristic information by virtue of issuing information about the location of one or more charging ports on-board said vehicle. By informing the user of the locations of the charging port(s), only when it is useful to do so, implicitly advises the user that the charge characteristic of their device is considered to be low or is considered to be being used up quickly, without necessitating the need to actually state that the charge characteristic of their device is considered to be low.

Optionally, issuing information about the location of one or more charging ports on-board said vehicle comprises providing visual information on a display screen on-board said vehicle. Additionally or alternatively, issuing information about the location of one or more charging ports on-board said vehicle comprises providing visual information on a display screen on said consumer electronic device. Such visual information may comprise an image of at least part of the vehicle and a demarcation on that image of the location of said one or more charging ports on-board said vehicle.

Optionally, issuing information about the location of one or more charging ports on-board said vehicle comprises providing visual information on, adjacent or otherwise proximate to at least one of said one or more charging ports on-board said vehicle. Such visual information may comprise an illumination on, adjacent or otherwise proximate to at least one of said one or more charging ports on-board said vehicle.

According to another aspect of the invention, there is provided a controller for use on-board a vehicle, the controller being connectable to a portable and rechargeable consumer electronic device by a first data connection, by virtue of which first data connection the controller is able to determine a charge characteristic of the consumer electronic device, the controller being configured and arranged to cause, in dependence upon said determined charge characteristic, information to be issued about the location of one or more charging ports on-board said vehicle.

Optionally, said charge characteristic includes data relating to one or more of the following: charge level of the battery of the consumer electronic device and rate of discharge of the battery of the consumer electronic device.

The controller may be additionally configured and arranged to cause charge characteristic information to be explicitly issued. Such explicitly issued charge characteristic information may be issued via a display or gauge. Alternatively or additionally, the controller may be configured and arranged to cause charge characteristic information to be implicitly issued by virtue of issuing information about the location of at least one of said one or more charging ports on-board said vehicle.

Optionally, the information issued about the location of at least one of said one or more charging ports on-board said vehicle comprises visual information on a display screen on-board said vehicle. Said visual information may comprise an image of at least part of the vehicle and a demarcation on that image of the location of at least one of said one or more charging ports on-board said vehicle.

The information issued about the location of at least one of said one or more charging ports on-board said vehicle by the controller may comprise visual information on, adjacent or otherwise proximate to at least one of said one or more charging ports on-board said vehicle. Such visual information may comprise an illumination on, adjacent or otherwise proximate to at least one of said one or more charging ports on-board said vehicle.

According to yet another aspect of the invention there is provided an infotainment system for a vehicle comprising a controller according to any of the relevant preceding paragraphs. The controller is connectable to a portable consumer electronic device by a first data connection, by means of which first data connection the controller is able to determine a charge characteristic of the consumer electronic device. The controller is configured and arranged to cause, in dependence upon said determined charge characteristic, information to be issued about the location of one or more charging ports on-board said vehicle.

According to a still further aspect of the invention, there is provided an infotainment system having a controller, wherein said controller comprises an electronic processor having an electrical input for receiving charge characteristic data from a portable and rechargeable consumer electronic device; and an electronic memory device, electrically coupled to the electronic processor, and having instructions stored therein. The controller causes, in dependence upon said received and/or determined charge characteristic, information to be issued about the location of one or more charging ports on-board said vehicle, and comprises the processor being configured to access the memory device and execute the instructions stored therein such that is operable to issue said information based on the charge characteristic.

According to even another further aspect of the invention, there is provided a controller for use on a consumer electronic device, the controller being able to determine a charge characteristic of the consumer electronic device, the controller being configured and arranged to cause, in dependence upon said determined charge characteristic, information to be issued about the location of one or more charging ports on-board a vehicle.

According to yet an even further aspect of the invention there is provided a vehicle comprising a controller according to any of the relevant preceding paragraphs.

According to yet an even further still aspect of the invention there is provided a vehicle comprising a controller, the controller being connectable to a portable consumer electronic device by a first data connection, by virtue of which first data connection the controller is able to determine a charge characteristic of the consumer electronic device, the controller being configured and arranged to cause, in dependence upon said determined charge characteristic, information to be issued about the location of one or more charging ports on-board said vehicle.

Within the scope of this application it is expressly intended that the various aspects, embodiments, examples and alternatives set out in the preceding paragraphs, in the claims and/or in the following description and drawings, and in particular the individual features thereof, may be taken independently or in any combination. That is, all embodiments and/or features of any embodiment can be combined in any way and/or combination, unless such features are incompatible. The applicant reserves the right to change any originally filed claim or file any new claim accordingly, including the right to amend any originally filed claim to depend from and/or incorporate any feature of any other claim although not originally claimed in that manner.

### BRIEF DESCRIPTION OF THE DRAWINGS

One or more embodiments of the invention will now be described, by way of example only, with reference to the accompanying drawings, in which:

FIG. 1 is a plan view of a motor vehicle schematically illustrating a dashboard mounted display screen, one or more charging ports, a consumer electronic device and a controller of an infotainment system according to an embodiment of the invention;

FIG. 2 is a perspective illustration of a cabin of the motor vehicle of FIG. 1 illustrating visual information in the form of an illumination on, adjacent or otherwise proximate to at least one of said one or more charging ports on-board the motor vehicle;

FIG. 3 is a flow diagram illustrating a method of assisting use of charging facilities on-board a vehicle according to an embodiment of the invention; and

FIG. 4 is an illustration of a display screen on-board the vehicle of FIG. 1 with an illustration of graphics and indicia displayed thereon.

### DETAILED DESCRIPTION

Detailed descriptions of specific embodiments of the methods, controllers, infotainment systems and vehicles of the present invention are disclosed herein. It will be understood that the disclosed embodiments are merely examples of the way in which certain aspects of the invention can be implemented and do not represent an exhaustive list of all of the ways the invention may be embodied. Indeed, it will be understood that the methods, controllers, infotainment systems and vehicles described herein may be embodied in various and alternative forms. The Figures are not necessarily to scale and some features may be exaggerated or minimised to show details of particular components. Well known components, materials or methods are not necessarily described in great detail in order to avoid obscuring the present disclosure. Any specific structural and functional details disclosed herein are not to be interpreted as limiting, but merely as a basis for the claims and as a representative basis for teaching one skilled in the art to variously employ the invention.

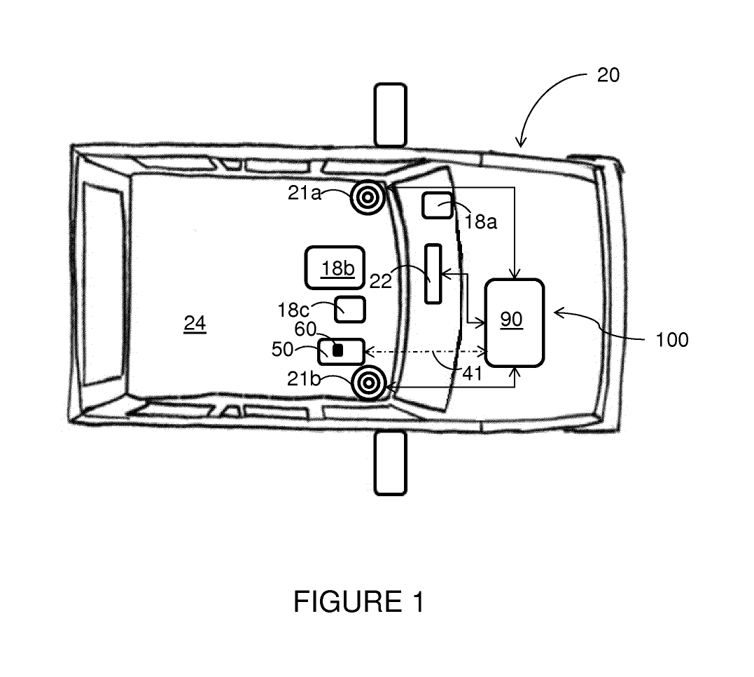

Referring to FIG. 1 a motor vehicle 20 is shown which has an on-board infotainment system 100. The infotainment system 100 comprises a controller 90 (also referred to as a head unit), one or more speakers 21a, 21b located about the cabin 24 of the vehicle 20 and a display screen 22. In the present embodiment, the controller 90 comprises an electronic processor (not shown) and the controller 90 comprises an electronic memory storage device (not shown) associated therewith. The electronic memory storage device may be a remote memory storage device accessible by the controller 90 and/or may be comprised within the controller 90. The electronic memory storage device has instructions stored therein that can be executed by the processor. The processor is capable of receiving input signals. In the present embodiment, the display screen 22 comprises a single display screen that is mounted within a dashboard of the vehicle 20. In other embodiments the number, position and style of display screen is different to that shown and may optionally include a head-up display. The controller 90 is connected to the display screen 22 and can cause graphics and images to be shown on the display screen 22.

The speakers 21a, 21b of the infotainment system 100 are connected to the head unit 90 (controller 90) and broadcast audio into the cabin 24. Audio broadcast by the speakers 21a, 21b may include music from a variety of sources including, for example and without limitation, an on-board CD player, a portable consumer electronic device 50 (referred to herein as device 50) and an on-board radio. Other audio signals that may be output by the amplifiers 21a, 21b include, for example and without limitation, telephone conversation from the portable consumer electronic device 50, information alerts and updates from on-board assistance systems (such as parking assist, seat belt wearing warnings, and the like), and other audible information such as satellite navigation information.

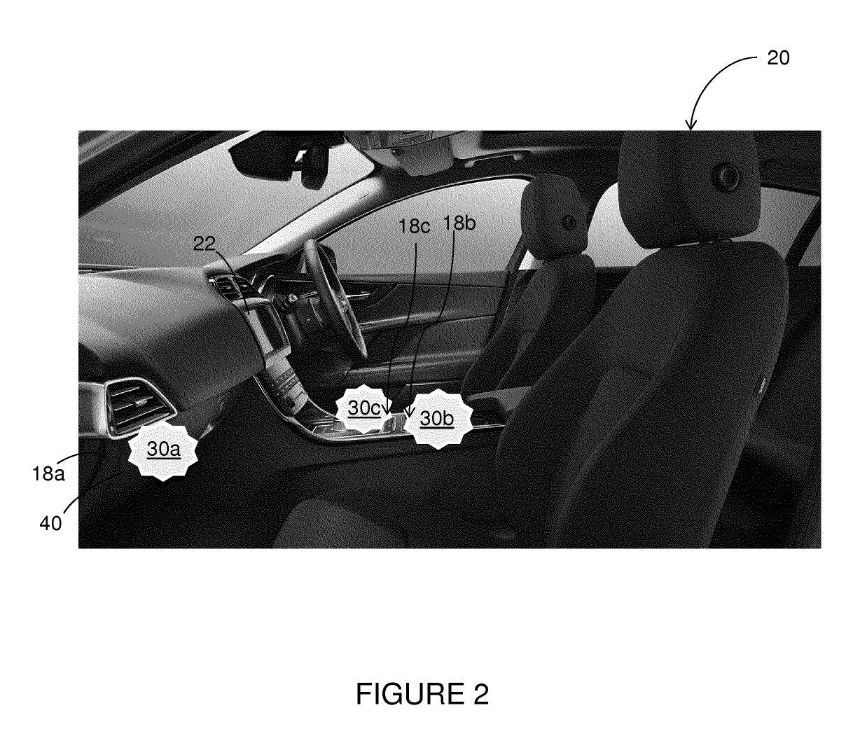

The motor vehicle 20 comprises device 50 charging facilities in the form of one or more charging ports 18a, 18b, 18c located about the motor vehicle cabin 24 and optionally the motor vehicle boot (trunk). In the presently illustrated embodiment, three charging ports 18a, 18b, 18c are provided, each of which connects to a battery of the vehicle 20 to supply electrical power to a device 50, such as the portable consumer electronic device 50, for recharging that device 50. A first charging port 18a is optionally located within a glove box 40 (see FIG. 2); a second charging port 18b, which takes the form of an inductive charging mat, is optionally located on or within a centre console between the driver's and front passenger's seats; and a third charging port 18c, in the form of a dock, is provided proximate the driver's seat and optionally also on or within the centre console.

The controller 90 of the present embodiment is connectable to the device 50, optionally in a wireless manner utilising for example Wi-Fi or Bluetooth® or other suitable wireless connectivity. In other embodiments the portable consumer electronic device 50 may be connectable to the controller 90 by a wired connection, for example using an on-board dock. The portable consumer electronic device 50 may take many and various forms and may be a device 50 used by the driver, by a passenger located in the front of the cabin 24 and/or by a passenger located in the rear of the cabin 24.

The controller 90 in the present embodiment is capable of connecting to more than one device 50 simultaneously, albeit only one such device 50 is shown in the Figures. The consumer electronic device(s) 50 may take many and various forms and for the purposes of non-limiting illustration only, the following non-exhaustive list of examples is provided: a smart phone, a mobile telephone, a portable computer, a tablet (computer), a portable music storage device such as an MP3 player or Ipod®, a video gaming device, a remote control, and an entertainment device such as a DVD player, Blu-Ray® player or electronic reader (e-book). It will be recognised that the invention disclosed herein may be utilised in applications where the consumer electronic device 50 is a different device compared to those listed here and the above list of possible formats that the consumer electronic device 50 may take is provided merely for illustrative purposes and to explain the vast application of the invention and is in no way intended and should in no way be taken as limiting. In other embodiments two or more similar or different consumer electronic devices 50 are connected to the controller 90 and in such an arrangement the methods described herein are performed for each of those two or more similar or different consumer electronic devices 50.

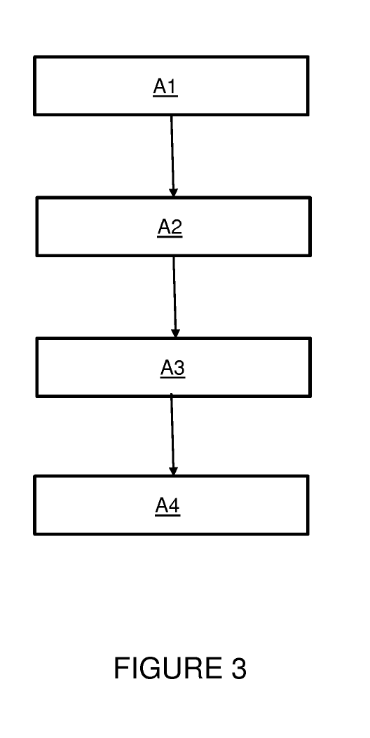

As shown in FIG. 1, the controller 90 connects to the consumer electronic device 50 via a first data connection 41. In this way, the consumer electronic device 50 can transmit data to the controller 90. In dependence upon the type of consumer electronic device 50, the data transmitted may vary. However in the presently illustrated arrangement, the consumer electronic device 50 transmits data relating to its identity and/or type, for example, “mobile smartphone”, “Apple® iPhone 4S®”. Additionally, the consumer electronic device 50 transmits data that enables the controller 90 to determine a “charge characteristic” of the consumer electronic device 50. Such data may include, for example a current battery charge level, in other words, a data value of the remaining battery life of the electronic device. The data value for the charge level may be provided as a percentage of the remaining battery life, or as an absolute value of remaining electrical charge. The determined “charge characteristic” may be based upon other data values in the alternative to or in addition to charge level. For example, a charge characteristic may be determined in dependence upon a whether the device 50 is currently being discharged and/or a rate of discharge if applicable. The controller 90 is configured to carry out a method of assisting or aiding use of the charging facilities 18a, 18b, 18c that are provided on-board the vehicle 20. The method may also be considered as a method of warning a user of a device 50 that the device 50 needs to be charged. The method is illustrated in FIG. 3 and in the present embodiment comprises the following:
A1: Determine that one or more devices 50 are connected to the controller 90 of the infotainment system 100 of the vehicle 20. This may be achieved by the electronic processor of the controller 90 of the infotainment system 100 having an electrical input for receiving data signal(s) from the device 50 and receiving signal(s) transmitted by the device 50.
A2: Determine a charge level of each of the devices 50 connected to the controller 90. This may be achieved by the electronic processor of the controller 90 having an electrical input for receiving battery charge level data from the device 50. The charge level may be received as a percentage of the remaining charge; a measurement of the remaining charge; and/or any other suitable quantifier for the expected remaining battery life of the device 50.
A3: Optionally determine a (current/real-time) rate of use of charge (rate of discharge) of each device 50. This may be achieved by the processor storing, on the electronic memory device associated therewith, sampled data over time of a real-time charge level of the battery of the consumer electronic device 50 and determining therefrom a rate of discharge of the battery of the consumer electronic device 50. Additionally or alternatively, this may be achieved by the processor receiving a signal comprising rate of discharge data from the consumer electronic device 50.
A4: Determine based upon the charge level and rate of discharge a charge characteristic and dependent upon that charge characteristic issue information about the location of one or more charging ports 18a, 18b, 18c on-board the vehicle 20. The issued information is to assist a user of the device 50 in locating a charging port 18a, 18b, 18c so that the user can plug their device 50 into the charging port 18a, 18b, 18c. This may be achieved by the processor being configured to access the memory device and execute the instructions stored therein such that the controller 90 is operable to issue said information 65, 67 based on the charge characteristic.

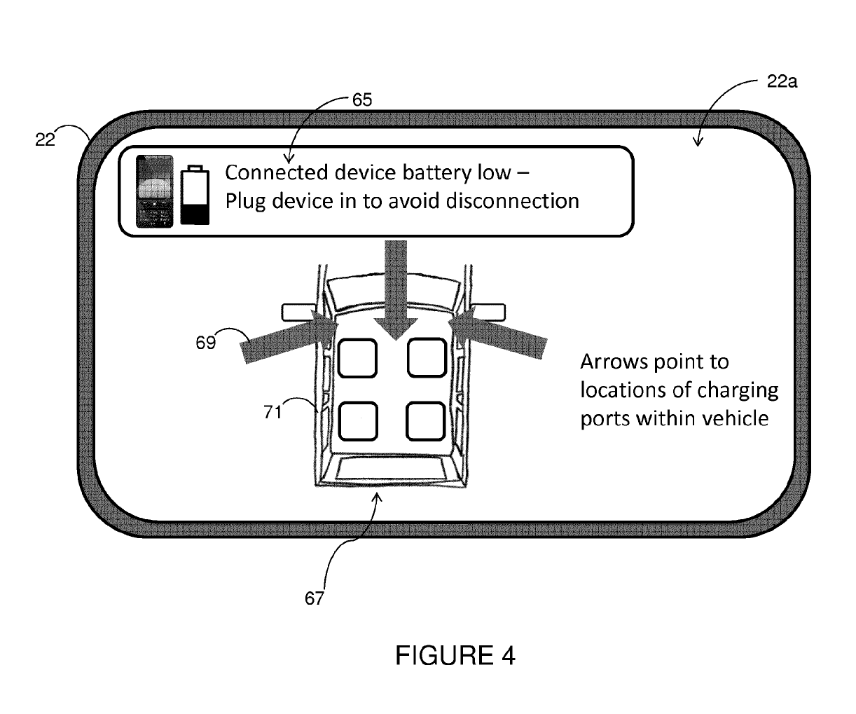

It is optional to determine a “charge characteristic” of each connected device 50 by considering both the charge level of the battery of the device 50 and a rate of use of charge (rate of discharge) of the battery of the device 50. However it is advantageous to consider the rate of use (rate of battery discharge) in order to prevent the charge level becoming critically low during use of the consumer electronic device 50. For example, in a first illustrative scenario, the driver of the vehicle 20 has a smartphone 50 which connects to the controller 90 via Bluetooth®. The controller 90 determines, from data provided to it from the smartphone 50, that the smartphone 50 has 50% of its battery life remaining. The smartphone 50 is not being used by the driver, albeit the smartphone 50 is switched on. As such the rate of use of the remaining 50% battery life is low and the controller 90 determines a charge characteristic (50% life, usage rate low) and based upon that charge characteristic, that no charging is required at this time. However, the controller 90 continues to monitor the device 50 and at some time later, the user receives or places a telephone call using the device 50 and the rate of use of the remaining 50% battery life significantly increases. The controller 90 then determines a new charge characteristic (50% life, discharge rate high) and determines based upon the new charge characteristic that charging of the smartphone 50 is advisable. This is because the charge characteristic, of 50% battery life and rate of use being high, indicates that there is a high risk that the battery life will drop below an acceptable level or deplete completely. Having made such a determination, the controller 90 causes information 67 (see FIG. 4) to be issued about the location of the three charging ports 18a, 18b, 18c disposed within the cabin 24.

The device 50 may comprise a second controller 60 which is optionally used to communicate with the controller 90 on-board the vehicle 20. The second controller 60, in the present arrangement, may be considered as a secondary controller provided only to facilitate a basic level of communication with the controller 90 on-board the vehicle and to supply charge characteristic data to the primary controller 90.

In the presently illustrated example, issuing information 67 about the location of the three charging ports 18a, 18b, 18c available on-board the vehicle 20 comprises providing visual information 67 on the display screen 22 mounted on the dashboard. Optionally, the visual information 67 comprises an image 71 of at least part of the vehicle and demarcations 69 on that image 71 of the locations of the three charging ports 18a, 18b, 18c. The image 71 of the vehicle may be a plan view, a perspective view and/or any other suitable view and be an image of only part of the vehicle 20. The demarcations 69 may take many and various forms. As shown in FIG. 4, the demarcations 69 optionally take the form of static arrows pointing at charging port 18a, 18b, 18c locations. In other arrangements, the demarcations 69 may be a flashing arrow; other indicia; other flashing indicia; a ring or other shape about the charging port 18a, 18b, 18c locations; and/or any other suitable means for indicating the position of one or more charging ports 18a, 18b, 18c, within the vehicle 20 (including the vehicle cabin 24 and/or the boot (trunk)).

Optionally, when the controller 90 causes information to be issued about the location of one or more charging ports 18a, 18b, 18c in addition to or instead of visual information 67 being shown by the display 22, visual information 30a, 30b, 30c may be provided on, adjacent or otherwise proximate to at least one of the one or more charging ports 18a, 18b, 18c on-board the vehicle 20. See FIG. 2, wherein the visual information 30a, 30b, 30c comprises an illumination 30a, 30b, 30c on, adjacent or otherwise proximate to at least one of, in this case each of, the charging ports 18a, 18b, 18c on-board the vehicle 20.

In the present embodiment, the method conducted by the controller 90 additionally, albeit optionally, includes explicitly issuing “charge characteristic” information 65. In the present embodiment, this is achieved by providing a symbol of a battery shown, for example, only half full, with optional accompanying text. As shown in FIG. 4, the text may state “Connected device battery low—Plug device in to avoid disconnection”. The explicitly issued “charge characteristic” information may comprise details relating to the battery level or remaining battery life and/or the rate of discharge of the battery and/or the identity of the device. In other embodiments the explicit charge characteristic information takes a different format and style to that shown here and different text is reproduced.

In the present arrangement, the method conducted by the controller 90 additionally, albeit optionally includes implicitly issuing charge characteristic information by virtue of issuing information 67 about the location of one or more charging ports 18a, 18b, 18c on-board the vehicle 20. In other words, it may not be necessary to indicate or state by information displayed as a visual, graphical or textual image 65 on a display 22 that a connected device 50 has a low battery level or is being discharged at a particular rate. Rather, the mere act of indicating where the charging ports 18a, 18b, 18c are located may be sufficient to relay to a user of the device 50 that the remaining battery life of the device 50 is considered to be low. Such implicit communication would be quickly learned by a user of the vehicle 20 who would only receive such implicit information when appropriate i.e. when a connected device 50 is considered to need recharging.

It can be appreciated that various changes may be made within the scope of the present invention. For example, in other embodiments of the invention it is envisaged that information about the charge characteristic and/or about the location of the charging ports may be provided by means of an audio signal. For example, a “voice-over” alert broadcast by an infotainment system may be issued to inform a user of a connected device that charging the device is recommended and/or may inform a user of a location of a charging port.

In some embodiments, the controller is configured to consider the type of connected device and whether particular charging locations are appropriate. For example, the second charging port 18b in the illustrated arrangement of FIG. 1 may take the form of an inductive coupling charging mat that is compatible only with certain devices. The controller may be provided with data (which may be stored in the electronic memory associated therewith and which data may be updated) relating to devices that are chargeable by that second charging port. For example, certain types of smartphone are chargeable by inductive coupling. The controller, upon recognising that the identified connected device is capable of such charging, may therefore include the second charging port 18b when it provides information 67 about the available charging locations. However, in some embodiments, the controller is arranged to only inform about the location of suitable charging ports. In a scenario where the connected device cannot be charged by inductive coupling, then the controller having determined that the connected device requires a conventional plug-in charging port would only provide information about the suitable charging ports 18a, 18c and would not provide information (whether audio or visual) about the location of the unsuitable inductive coupling charging port 18b.

In some embodiments the controller and methods of the present disclosure are arranged to accommodate more than one connected device. In such embodiments, an identifier for each device will be transmitted to the controller (and received by the electronic processor), for example via the Bluetooth® connection such that the controller can identify each device and determine the “charge characteristic” of each device. Since the charge characteristic may not be the same for each device, recharging may not be recommended for all devices and in such embodiments, the information issued by the controller may additionally include an indicator about the identity of the connected device to which the recharging guidance warning applies.

In some embodiments the controller is configured to learn or recognise patterns in user behaviour associated with particular devices. For example, the controller may store information about when it has recommended recharging for a particular device, the location (based on GPS) of the vehicle at that time; the journey being undertaken at that time (based upon navigational data), the “charge characteristic” of that particular device at that time, and whether recharging was carried out or not. In this way the controller can learn, for example, that on a particular journey (for example, the device user returning home from work) that when a warning is issued at a battery level of 30% or more, that the user typically does not plug-in the device. The controller may be configured to learn this behaviour and to stop issuing warnings, alerts and/or implicit charging port location guidance when that same scenario occurs in future.

In some embodiments it is envisaged that the “controller” may comprise one or more controllers. In some embodiments comprising two or more controllers, a first controller is (permanently) on-board the vehicle and the second controller is located within or on or otherwise directly associated with the consumer electronic device itself (such that it is only temporarily on-board the vehicle or removable therefrom). For example, the second controller may form part of an application (“app”) that may be installed, for example by being downloaded, onto the consumer electronic device. In such embodiments, the first and second controllers between them are configured to carry out the method of assisting or aiding use of the charging facilities that are provided on-board the vehicle.

It is envisaged that the first and second controllers may “share” the tasks of the method between them in a variety of ways. For example, in some embodiments the method of assisting use of a portable and rechargeable consumer electronic device on-board a vehicle is achieved by the second controller determining a charge characteristic of the consumer electronic device; and in dependence upon said determined charge characteristic, the second controller signalling, instructing or otherwise causing the first controller to issue information about the location of one or more charging ports.

In other embodiments, the method of assisting use of a portable and rechargeable consumer electronic device on-board a vehicle is achieved by the second controller determining a charge characteristic of the consumer electronic device; and in dependence upon said determined charge characteristic, the second controller issuing information about the location of one or more charging ports. Such information may be issued on a screen of the consumer electronic device itself. In some such embodiments, the second controller may communicate with the first controller to determine the information about the location of one or more charging ports. Additionally or alternatively, the information about the location of one or more charging ports may be stored in a memory on or associated with the second controller. For example, the information about the location of one or more charging ports for a particular vehicle may be supplied as part of the installed “app”.

In embodiments using a second controller of the consumer electronic device to determine a charge characteristic of the consumer electronic device; and in dependence upon said determined charge characteristic cause information to be issued about the location of one or more charging ports, such information may be issued on or by the device and/or on or by the vehicle. Additionally, the second controller may determine that the consumer electronic device is (currently) on-board the vehicle (such that use of the “app” is appropriate). This may be done by the second controller on the consumer electronic device being in communication with a first controller on-board the vehicle. Alternatively, the second controller may determine that the consumer electronic device is on-board the vehicle by some other means, for example by means of visual identification of its location, and/or by means of being activated by a user of the device.

As used herein the terms “connected”, “connectable” and “in communication with” refer to all manner of suitable ways in which a consumer electronic device can co-operate, converse, correspond, or otherwise interact with a controller, which co-operation may be achieved by means of a wireless connection. Wireless communication may be facilitated by any suitable means, including, but not exclusively, for example, Bluetooth® and Wi-Fi.

1. A method of assisting use of a portable and rechargeable consumer electronic device on-board a vehicle, the method comprising:
determining a charge characteristic of the consumer electronic device; and
in dependence upon the determined charge characteristic, issuing information about a location of one or more charging ports on-board the vehicle.

2. The method according to claim 1, further comprising determining that the consumer electronic device is in communication with a controller of a vehicle system on-board the vehicle, optionally wherein the determining that the consumer electronic device is in communication with the controller of the vehicle system on-board the vehicle comprises receiving data from the consumer electronic device, wherein the data comprises one or more of the following: charge level of a battery of the consumer electronic device, identity of the battery of the consumer electronic device, and type of consumer electronic device.

3. (canceled)

4. The method according to claim 2, wherein the consumer electronic device is in wireless communication with the controller of the vehicle system on-board the vehicle.

5. The method according to claim 1, wherein the determining the charge characteristic comprises receiving data relating to one or more of the following: charge level of a battery of the consumer electronic device and rate of discharge of the battery of the consumer electronic device.

6. The method according to claim 1, wherein the issuing information comprises explicitly issuing charge characteristic information, optionally wherein the explicitly issuing charge characteristic information comprises issuing an audible or visual warning that incorporates a statement about one or more of the following: the charge characteristic of the consumer electronic device, a charge level of a battery of the consumer electronic device, and a rate of discharge of the battery of the consumer electronic device.

7. (canceled)

8. The method according to claim 1, wherein the issuing information comprises implicitly issuing charge characteristic information by issuing information about the location of the one or more charging ports on-board the vehicle.

9. The method according to claim 1, wherein the issuing information about the location of the one or more charging ports on-board the vehicle comprises providing visual information on a display screen on-board the vehicle and/or on a display screen on the consumer electronic device.

10. (canceled)

11. The method according to claim 9, wherein the visual information comprises an image of at least part of the vehicle and a demarcation on the image of the location of the one or more charging ports on-board the vehicle.

12. The method according to claim 1, wherein the issuing information about the location of the one or more charging ports on-board the vehicle comprises providing visual information on, adjacent or otherwise proximate to at least one of the one or more charging ports on-board the vehicle, optionally wherein the visual information comprises illumination on, adjacent or otherwise proximate to at least one of the one or more charging ports on-board the vehicle.

13. (canceled)

14. A controller for use on-board a vehicle,
wherein the controller is connectable to a portable and rechargeable consumer electronic device by a first data connection,
wherein the controller is configured to determine a charge characteristic of the consumer electronic device via the first data connection, and
wherein the controller is configured to cause, in dependence upon the determined charge characteristic, information to be issued about a location of one or more charging ports on-board the vehicle.

15. The controller according to claim 14, wherein the charge characteristic comprises data relating to one or more of the following: charge level of a battery of the consumer electronic device and rate of discharge of the battery of the consumer electronic device.

16. The controller according to claim 14, wherein the controller is additionally configured to cause charge characteristic information to be explicitly issued, or wherein the controller is configured to cause the charge characteristic information to be implicitly issued by issuing information about the location of at least one of the one or more charging ports on-board the vehicle.

17. (canceled)

18. The controller according to claim 14, wherein the information issued about the location of at least one of the one or more charging ports on-board the vehicle comprises visual information on a display screen on-board the vehicle.

19. The controller according to claim 18, wherein the visual information comprises an image of at least part of the vehicle and a demarcation on the image of the location of at least one of the one or more charging ports on-board the vehicle.

20. The controller according to claim 14, wherein the information issued about the location of at least one of the one or more charging ports on-board the vehicle comprises visual information on, adjacent or otherwise proximate to at least one of the one or more charging ports on-board the vehicle.

21. The controller according to claim 20, wherein the visual information comprises illumination on, adjacent or otherwise proximate to at least one of the one or more charging ports on-board the vehicle.

22. An infotainment system for a vehicle comprising the controller according to claim 14.

23. A vehicle comprising the controller according to claim 14.

24. A vehicle comprising an infotainment system comprising the controller according to claim 14.

25. A controller for use on a consumer electronic device, wherein the controller is configured to determine a charge characteristic of the consumer electronic device, wherein the controller is configured to cause, in dependence upon the determined charge characteristic, information to be issued about a location of one or more charging ports on-board a vehicle.

26. (canceled)
